(19) United States
(12) Patent Application Publication
(10) Pub. No.: US 2026/0051038 A1
(43) Pub. Date: Feb. 19, 2026

(54) SYSTEMS AND METHODS FOR ENHANCED WAFER MANUFACTURING

(71) Applicant: GlobalWafers Co., Ltd., Hsinchu (TW)

(72) Inventors: Tsung Chieh Lin, Hsinchu (TW); Sumeet Bhagavat, St. Charles, MO (US)

(21) Appl. No.: 19/303,900

(22) Filed: Aug. 19, 2025

Related U.S. Application Data
(60) Provisional application No. 63/684,676, filed on Aug. 19, 2024.

(51) Int. Cl. G06T 7/00; H01L 21/66

(52) U.S. Cl. CPC G06T 7/0004; H01L 22/12; G06T 2207/20081; G06T 2207/30148

(57) ABSTRACT

A computer device is provided. The computer device includes at least one processor in communication with at least one memory device. The at least one processor is programmed to store, in the at least one memory device, a model for predicting post-grinding thickness of a wafer; receive scan data of a first inspection of a wafer; execute the model using the scan data as inputs to determine a final thickness of the wafer; compare the final thickness to one or more thresholds; determine if the final thickness exceeds at least one of the one or more thresholds; and cause a grinding station to be adjusted when it is determined that the final thickness exceeds at least one of the one or more thresholds.

### CROSS REFERENCE TO RELATED APPLICATIONS

This application claims the benefit of and priority to U.S. Provisional Application No. 63/684,676, filed Aug. 19, 2024, which application is hereby incorporated by reference in its entirety.

### FIELD

The field relates generally to enhanced wafer manufacturing and, more specifically, to enhanced wafer analysis using a neural network to predict wafer thickness during double grinding (DGRD).

### BACKGROUND

Semiconductor wafers are commonly used as substrates in the production of integrated circuit (IC) chips. Chip manufacturers require wafers that have extremely flat and parallel surfaces to ensure that a maximum number of chips can be fabricated from each wafer. After being sliced from an ingot, wafers typically undergo grinding and polishing processes designed to improve certain surface features, such as flatness and parallelism.

Simultaneous double side grinding operates on both sides of a wafer at the same time and produces wafers with highly planarized surfaces. These grinders use a wafer-clamping device to hold the semiconductor wafer during grinding. The clamping device typically comprises a pair of hydrostatic pads and a pair of grinding wheels. The pads and wheels are oriented in opposed relation to hold the wafer therebetween in a vertical orientation. The hydrostatic pads beneficially produce a fluid barrier between the respective pad and wafer surface for holding the wafer without the rigid pads physically contacting the wafer during grinding. This reduces damage to the wafer that may be caused by physical clamping and allows the wafer to move (rotate) tangentially relative to the pad surfaces with less friction. While this grinding process can improve flatness and/or parallelism of the ground wafer surfaces, it can cause degradation of the topology of the wafer surfaces. Specifically, misalignment of the hydrostatic pad and grinding wheel clamping planes are known to cause such degradation. Post-grinding polishing produces a highly reflective, mirrored wafer surface on the ground wafer but does not address topology degradation.

In order to identify and address topology degradation concerns, device and semiconductor material manufacturers consider the nanotopography of the wafer surfaces by relying on grinder sensors. Furthermore, engineers design grinder recipes based on trial-and-error experience. When a sensor malfunction or wrong recipe setting occurs, yield loss or quality issues may arise.

In some current systems, potentially hundreds of wafers are processed after grinding before problems may be detected in the grinding process. Furthermore, each individual production line and grinder may have particular characteristics, which may vary from device to device. Accordingly, there is a need for a system for analyzing wafers to quickly and efficiently detect potential issues in the grinding process to prevent significant losses in time and material.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a computer device includes at least one processor (or “the processor) in communication with at least one memory device. The processor is programmed to store, in the at least one memory device, a model for predicting post-grinding thickness of a wafer. The processor is also programmed to receive scan data of a first inspection of a wafer. The processor is programmed to execute the model using the scan data as inputs to determine a final thickness of the wafer. The processor is programmed to compare the final thickness to one or more thresholds. In addition, the processor is programmed to determine if the final thickness exceeds at least one of the one or more thresholds. Moreover, the processor is programmed to cause a grinding station to be adjusted when it is determined that the final thickness exceeds at least one of the one or more thresholds. The computer device may have additional, less, or alternate functionalities, including those discussed elsewhere herein.

In another aspect, a method for analyzing a wafer is performed by a computing device including at least one processor in communication with at least one memory device. The method includes storing, in the at least one memory device, a model for predicting post-grinding thickness of a wafer. The method also includes receiving scan data of a first inspection of a wafer. The method further includes executing the model using the scan data as inputs to determine a final thickness of the wafer. Moreover, the method includes comparing the final thickness to one or more thresholds. In addition, the method includes determining if the final thickness exceeds at least one of the one or more thresholds. Moreover, the method further includes causing a grinding station to be adjusted when it is determined that the final thickness exceeds at least one of the one or more thresholds. The method may have additional, less, or alternate functionalities, including those discussed elsewhere herein.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 illustrates a block diagram of a system for processing semiconductor wafers in accordance with at least one embodiment of the disclosure.

FIG. 2 is a flowchart illustrating an example process of evaluating a wafer using the system shown in FIG. 1.

FIG. 3 is a simplified block diagram of an example system for evaluating a wafer using the process shown in FIG. 2 in accordance with the system shown in FIG. 1.

FIG. 4 illustrates an example configuration of a client system of the system shown in FIG. 3, in accordance with one embodiment of the present disclosure.

FIG. 5 illustrates an example configuration of a server system of the system shown in FIG. 3, in accordance with one embodiment of the present disclosure.

FIG. 6 illustrates a block diagram of a prediction model for post-DGRD wafer thickness in accordance with at least one embodiment of the disclosure.

FIG. 7 illustrates a first part of a detailed deep learning architecture.

FIG. 8 illustrates a second part of a detailed deep learning architecture.

FIG. 9 illustrates a graph of outlier information for an example grinder shown in FIG. 1.

FIG. 10 illustrates a graph illustrating a correlation and R-square between ground truth and prediction of post-DGRD thickness when provided for an example.

Corresponding reference characters indicate corresponding parts throughout the several views of the drawings.

### DETAILED DESCRIPTION

The implementations described herein relate to systems and methods for analyzing wafer data and, more specifically, to use of neural networks to predict wafer thickness during double grinding (DGRD). More specifically, a wafer surface analysis model is executed by a computing device to (1) determine current conditions of a wafer; (2) predict a post-grinding state of conditions of the wafer based on the current conditions and the model; and (3) determine if adjustments need to be made to the grinder based on the post-grinding state of the wafer and one or more predetermined thresholds. The systems and methods described herein provide feedback in less time, allowing adjustments that can be made to improve analysis to be recognized and implemented with less lag time for improved quality control and/or wafer yield.

Double sided grinding is one process, which governs the nanotopography of finished wafers. Nanotopography defects like C-Marks ((peak-to-valley) PV value generally within a radius of 0 to 50 mm of center) and B-Rings (PV value generally within a radius of 100 to 150 mm of center) take form during grinding process and may lead to substantial yield losses. A third defect which leads to losses due to nanotopography is the entrance mark produced on the wafer during wire saw slicing. Double sided grinding can potentially reduce the entrance mark if the grinding wheels are favorably oriented with respect to the wafer. Then the wafer is etched and is measured using a laser based tool. After this, the wafer undergoes various downstream processes like edge polishing, double sided polishing, and final polishing as well as measurements for flatness and edge defects before the nanotopography is checked by a nanomapper.

The present systems and methods describe using a neural network on process log data to predict real-time DGRD process thickness which is currently controlled by thickness sensors of the grinder. In this approach the system analyzes real-time grinder parameters, previous historical wafer logs, and process recipes which include settings of process steps, feeding speed setting and thickness status, and further predict next-step thickness. Then the system determines the relationships between input data and thickness output to design improved recipes and/or to select a specific grinder to meet specific customer specification and quality.

The systems and processes are not limited to the specific embodiments described herein. In addition, components of each system and each process can be practiced independent and separate from other components and processes described herein. Each component and process also can be used in combination with other assembly packages and processes.

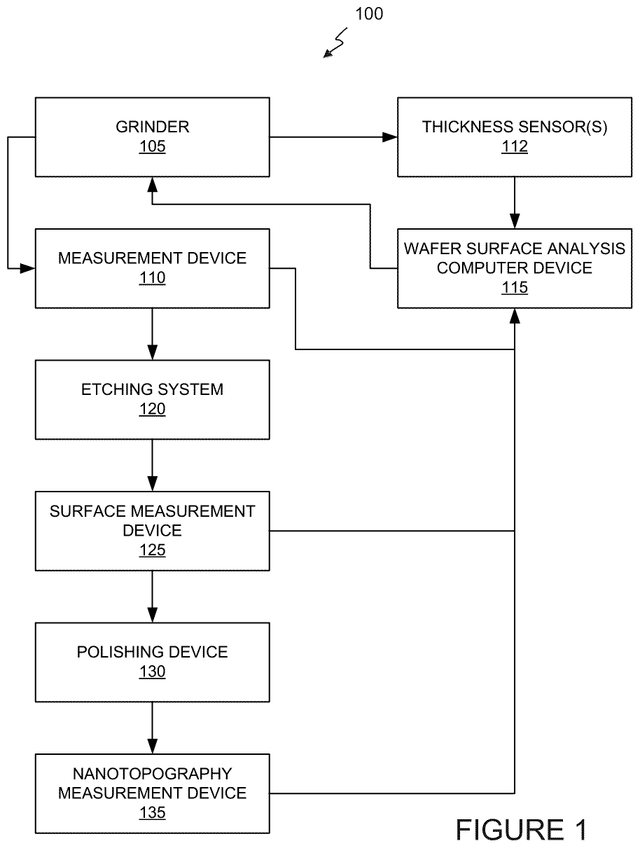

FIG. 1 illustrates a block diagram of a system 100 for processing semiconductor wafers in accordance with at least one embodiment of the disclosure. For the purposes of this disclosure, system 100 starts with the grinder 105 in the process of silicon wafer manufacture. In the example embodiment, the grinder 105 is a double-sided grinder as described above. In other embodiments, the grinder 105 may only be a single sided grinder.

In the example embodiment, the system 100 includes one or more thickness sensors 112 that are used to measure attributes of a wafer before, during, and/or after grinding. These sensors 112 report their information to the WSA computer device 115. In the example embodiment, the WSA computer device 115 includes a model of the grinders 105 in system 100, where the model determines the thickness of wafers based on information from sensors 112. The WSA computer device 115 executes a neural network to predict real-time DGRD process thickness. The model analyzes real-time grinder parameters, previous historical wafer log, and process recipes, which include settings of process steps, feeding speed setting and thickness status, to predict wafer thickness. In some embodiments, the thickness sensors 112 measure the wafer after the grinding is complete. In other embodiments, the thickness sensors 112 measure the wafer while the grinding is occurring.

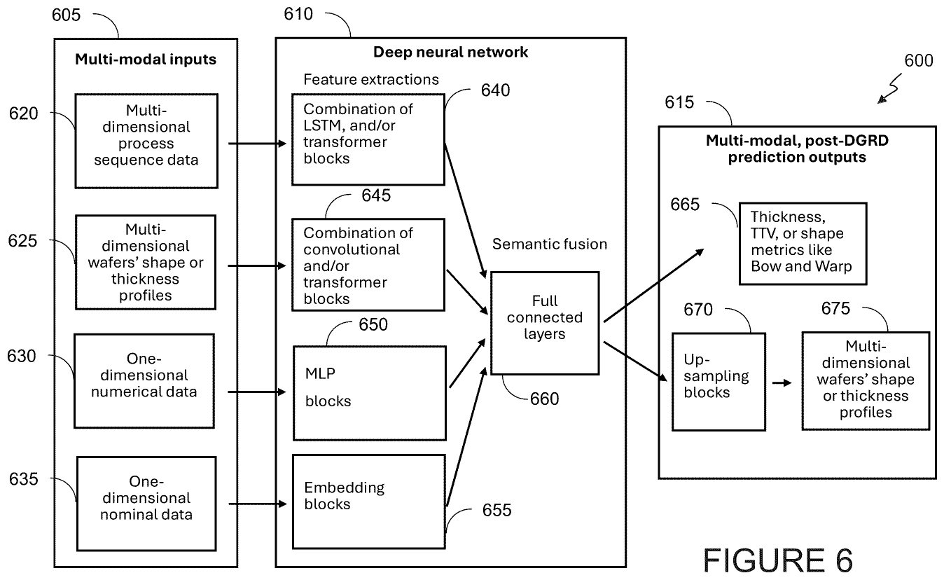

After the grinder 105 grinds the wafer, the wafer is analyzed by a measurement device 110, which measures data to generate a profile for the ground wafer. At this point, the wafer is unetched and unpolished. In some further embodiments, the measurement device 110 provides the measurement data from the ground wafer to a wafer surface analysis (WSA) computer device 115. In some embodiments, measurement device 110 uses a capacitance probe or a laser-based distance sensor to measure the wafers. Examples of how measurement device 110 analyzes a wafer may be found below in the description of FIGS. 6-9. The WSA computer device 115 analyzes the measurement data of the wafer to determine the profile of the wafer after polishing. If the determined profile exceeds any quality thresholds, then the WSA computer device 115 may determine that the grinder 105 needs to be adjusted. In some embodiments, the WSA computer device 115 receives scan data of a first inspection of a wafer, where the first inspection is performed by the one or more thickness sensors 112 and the scan data includes data from the one or more thickness sensors 112. In some further embodiments, the WSA computer device 115 also receives scan data from the measurement device 110.

In some other embodiments, the system 100 includes a plurality of grinders 105, where each grinder 105 grinds a wafer, but each wafer may only be ground once. In these embodiments, the WSA computer device 115 tracks the grinding results of each of the plurality of grinders 105.

In some embodiments, the WSA computer device 115 determines an adjustment to the grinder(s) 105 based on the predicted wafer thickness. In some of these embodiments, the adjustments to the grinder(s) 105 are made during the grinding of the wafer to adjust the final results. In other embodiments, the adjustments are made prior to the grinding. In still further embodiments, the adjustments are made after the grinding is complete as the adjustment is for subsequent wafers.

In the example embodiment, system 100 includes a plurality of post grinding devices, such as, but not limited to, an etching device 120 for etching the ground wafer, a surface measurement device 125 for measuring the flatness of the surface of the etched wafer, a polishing device 130 for polishing the etched wafer, and a nanotopography measurement device 135 the nanotopography of the polished wafer. In other embodiments, other devices may be included in the system 100.

In some embodiments, the WSA computer device 115 receives scan data of a wafer from one or more of the thickness sensors 112, the measurement device 110, the surface measurement device 125, and/or the nanotopography measurement device 135.

In the example embodiment, the WSA computer device 115 creates a model for each system 100 that it analyzes. For example, a factory may have more than one production line for manufacturing wafers, where each production line includes its own grinders 105. For each production line, the WSA computer device 115 generates a separate model for those grinders 105.

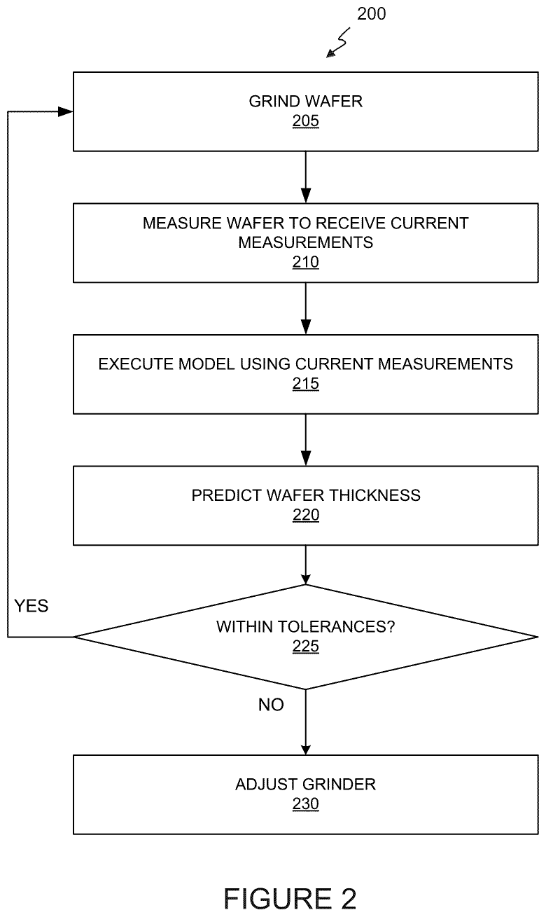

FIG. 2 is a flowchart illustrating an example process 200 of evaluating a wafer using the system 100 (shown in FIG. 1). In the example embodiment, steps of process 200 are performed by the WSA computer device 115 (shown in 1).

In the example embodiment, the grinder 105 grinds 205 the wafer. This may be a double-sided grinder 105 as described above or any other grinder configured to work the system 100 described herein. In some embodiments, one or more thickness sensors 112 (shown in FIG. 1) measure 210 the wafer. In different embodiments, the wafer is measured by the thickness sensors 112, before, during, and/or after the grinding process. The measurements of the wafer are transmitted to the WSA computer device 115. The WSA computer device 115 executes 215 a model of the system 100 using the current measurements of the wafer as inputs. In the example embodiment, the measurements of the wafer are of the wafer as measured by the thickness sensors 112. The WSA computer device 115 uses the execution of the model to generate 220 a predicted thickness for the wafer. The predicted wafer thickness predicts the expected thickness of the wafer post grinding, such as would be measured by the thickness sensors 112.

The WSA computer device 115 compares 225 the predicted wafer thickness to one or more predetermined thresholds. In the example embodiment, the predetermined thresholds are requirements for the proper thickness of the wafer post grinding. In the example embodiment, some of the predetermined thresholds and/or requirements are based on one or more user preferences, from the manufacturer of the wafer and/or the customer purchasing the wafer.

If the wafer is within tolerances 225, not exceeding the predetermined thresholds, the system 100 continues to step 205 and either continues to grind the current wafer or grinds the next wafer. If the wafer is not within tolerances 225, the WSA computer device 115 adjusts 230 the grinder 105. In some embodiments, the WSA computer device 115 directly adjusts 230 the grinder 105. In other embodiments, the WSA computer device 115 instructs another device to adjust 230 the grinder 105. In still further embodiments, the WSA computer device 115 instructs a user to adjust 230 the grinder 105. After the grinder 105 is adjusted 230, the system 100 proceeds to step 205 and either continues to grind the present wafer and/or grinds the next wafer.

In some embodiments, the WSA computer device 115 determines that the wafer is within tolerances 225, but also determines that the grinder 105 is no longer properly adjusted. In these embodiments, the WSA computer device 115 may determine that the grinder 105 is drifting out of proper adjustment based on a current trend of the grinding inspections of a plurality of wafers. The WSA computer device 115 may recognize the trend and determine that the grinder 105 will need adjustment in a specific number of uses or after a period of time. In these embodiments, the WSA computer device 115 may determine when the next planned period of downtime is for the system 100. If the planned period of downtime is before the grinder is expected to come out of proper adjustment, the WSA computer device 115 may schedule the grinder adjustment to occur during the planned period of downtime. The WSA computer device 115 may determine when the grinder 105 is expected to generate out of tolerance wafers based on the one or more predetermined thresholds, the amount of change in post grinding results for each wafer, and the model.

In the example embodiment, the WSA computer device 115 generates the model based on a plurality of historical data including one or more grinding process logs, grinding recipes, and grinder sensor data, such as from thickness sensors 112 and/or measurement device 110. The grinding process logs are logs for each wafer as a real-time recording per second to record detailed machine status or settings. Examples of these settings include, but are not limited to, wheel current, wheel position, wheel tilt parameters, wheel size, etc. The grinding recipe include attributes including, but not limited to, feeding speed, target thickness, steps, etc. In some embodiments, the model may consider one or more of past post grinding measurements by the measurement device 110 and/or thickness sensor(s) 112, past post etching measurements by the surface measurement device 125, and past post polishing measurements by the nanotopography measurement device 135 (all shown in FIG. 1).

In the example embodiment, the WSA computer device 115 generates the model by comparing the one or more grinding process logs, the grinding recipes, and during and post grinding measurements of wafers to determine how the system 100 changes the wafer as it is grinder 105.

The dataset details include the following data outputs of the prediction model a prediction target. The prediction target may be a model output that includes post-DGRD wafer thickness with wafer metrics. The prediction model and system data flow design may involve feature or sequence information extraction, including a combination of multilayer perceptron (MLP), long short-term memory (LSTM), and convolutional layers to handle sequence type data.

While the above system 100 and process 200 are described for semiconductor wafer manufacturing using grinders 105, one of skill in the art would understand that this disclosure may be used with other products and devices.

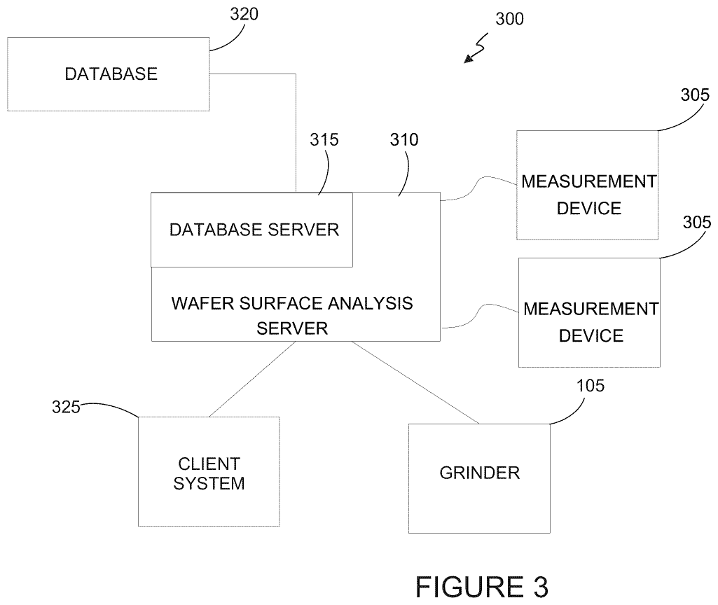

FIG. 3 is a simplified block diagram of an example system 300 for evaluating a wafer using the process 200 (shown in FIG. 2) in accordance with the system 100 (shown in FIG. 1). In the example embodiment, system 300 is used for analyzing wafers during and post-grinding to determine wafer thickness post-grinding. In addition, system 300 is a real-time data analyzing and classifying computer system that includes a wafer surface analysis (WSA) computer device 310 (also known as a WSA server) configured to analyze wafers and predict future states based on the analysis.

In the example embodiment, a measurement device 305 is configured to scan the thickness of a wafer to determine thickness of that wafer. More specifically, the measurement device 305 scans the thickness of the wafer before, during, and/or after grinding and is in communication with the WSA computer device 310. The measurement device 305 connects to the WSA computer device 310 through various wired or wireless interfaces including without limitation a network, such as a local area network (LAN) or a wide area network (WAN), dial-in-connections, cable modems, Internet connection, wireless, and special high-speed Integrated Services Digital Network (ISDN) lines. The measurement device 305 receives data about the thickness of a wafer and reports that data to the WSA computer device 310. In other embodiments, the measurement device 305 is in communication with one or more client systems 325 and the client systems 325 route the measurement data to the WSA computer device 310 in real-time or near real-time. In the example embodiment measurement device 305 includes one or more of measurement device 110, thickness sensors 112, surface measurement device 125, and nanotopography measurement device 135 (all shown in FIG. 1).

As described above in more detail, the WSA server 310 is programmed to analyze wafers to predict the thickness of the wafer surface post-grinding to allow the system 300 to respond to changes that would cause the wafer to be out of tolerance quickly. The WSA server 310 is programmed to (1) determine current conditions of a wafer including thickness; (2) predict a post-grinding state of conditions of the wafer based on the current conditions and the model; and (3) determine if adjustments need to be made to the grinder based on the post-grinding state of the wafer and one or more predetermined thresholds. In the example embodiment, the WSA server 310 is similar to wafer surface analysis computer device 115 (shown in FIG. 1).

In the example embodiment, client systems 325 are computers that include a web browser or a software application, which enables client systems 325 to communicate with the WSA server 310 using the Internet, a local area network (LAN), or a wide area network (WAN). In some embodiments, client systems 325 are communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem. Client systems 325 can be any device capable of accessing a network, such as the Internet, including, but not limited to, a desktop computer, a laptop computer, a personal digital assistant (PDA), a cellular phone, a smartphone, a tablet, a phablet, or other web-based connectable equipment.

A database server 315 is communicatively coupled to a database 320 that stores data. In one embodiment, database 320 is a database that includes historical data and the model. In some embodiments, database 320 is stored remotely from WSA server 310. In some embodiments, database 320 is decentralized. In the example embodiment, a person can access database 320 via client systems 325 by logging onto WSA server 310.

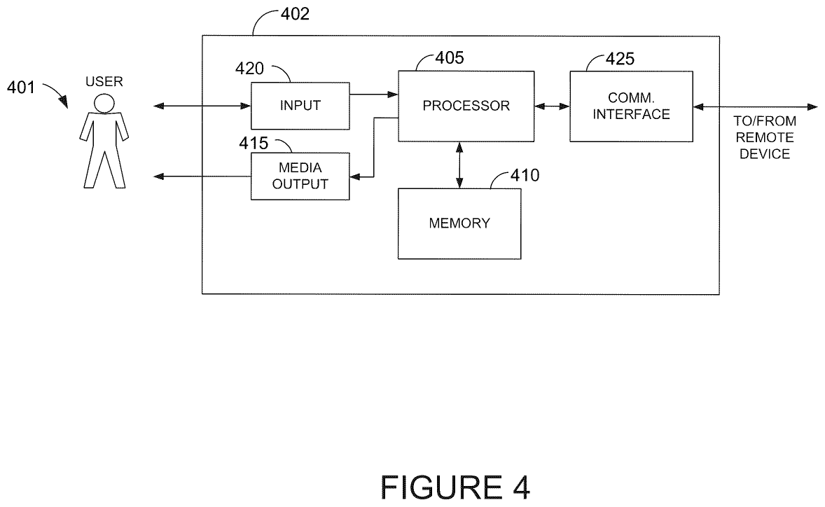

FIG. 4 illustrates an example configuration of client system 325 (shown in FIG. 3) of the system 300 (shown in FIG. 3), in accordance with one embodiment of the present disclosure. User computer device 402 is operated by a user 401. User computer device 402 may include, but is not limited to, measurement device 110, wafer surface analysis computer device 115, surface measurement device 125, nanotopography measurement device 135 (all shown in FIG. 1), measurement device 305, WSA computer device 310, and client systems 325 (all shown in FIG. 3). User computer device 402 includes a processor 405 for executing instructions. In some embodiments, executable instructions are stored in a memory area 410. Processor 405 may include one or more processing units (e.g., in a multi-core configuration). Memory area 410 is any device allowing information such as executable instructions and/or transaction data to be stored and retrieved. Memory area 410 may include one or more computer-readable media.

User computer device 402 also includes at least one media output component 415 for presenting information to user 401. Media output component 415 is any component capable of conveying information to user 401. In some embodiments, media output component 415 includes an output adapter (not shown) such as a video adapter and/or an audio adapter. An output adapter is operatively coupled to processor 405 and operatively coupleable to an output device such as a display device (e.g., a cathode ray tube (CRT), liquid crystal display (LCD), light emitting diode (LED) display, or “electronic ink” display) or an audio output device (e.g., a speaker or headphones). In some embodiments, media output component 415 is configured to present a graphical user interface (e.g., a web browser and/or a client application) to user 401. A graphical user interface may include, for example, an interface for viewing the results of the analysis of one or more wafers. In some embodiments, user computer device 402 includes an input device 420 for receiving input from user 401. User 401 may use input device 420 to, without limitation, select a wafer to view the analysis of. Input device 420 may include, for example, a keyboard, a pointing device, a mouse, a stylus, a touch sensitive panel (e.g., a touch pad or a touch screen), a gyroscope, an accelerometer, a position detector, a biometric input device, and/or an audio input device. A single component such as a touch screen may function as both an output device of media output component 415 and input device 420.

User computer device 402 may also include a communication interface 425, communicatively coupled to a remote device such as WSA server 310 (shown in FIG. 3). Communication interface 425 may include, for example, a wired or wireless network adapter and/or a wireless data transceiver for use with a mobile telecommunications network.

Stored in memory area 410 are, for example, computer-readable instructions for providing a user interface to user 401 via media output component 415 and, optionally, receiving and processing input from input device 420. A user interface may include, among other possibilities, a web browser and/or a client application. Web browsers enable users, such as user 401, to display and interact with media and other information typically embedded on a web page or a website from WSA server 310. A client application allows user 401 to interact with, for example, WSA server 310. For example, instructions may be stored by a cloud service, and the output of the execution of the instructions sent to the media output component 415.

Processor 405 executes computer-executable instructions for implementing aspects of the disclosure. In some embodiments, the processor 405 is transformed into a special purpose microprocessor by executing computer-executable instructions or by otherwise being programmed.

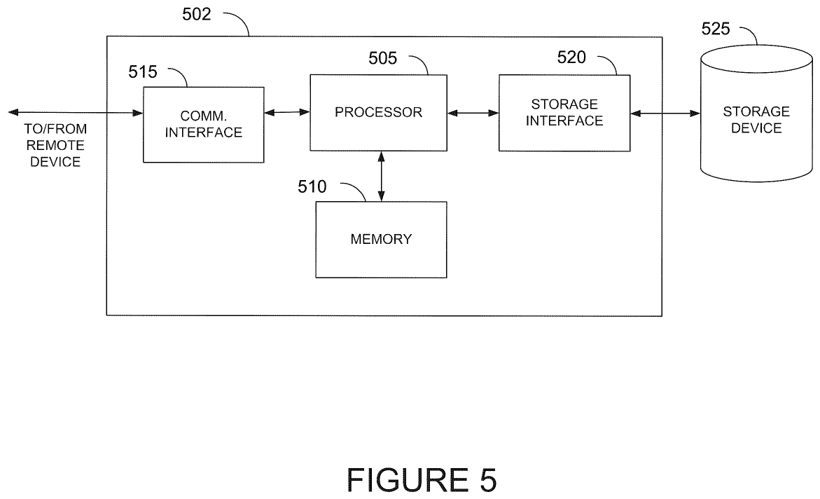

FIG. 5 illustrates an example configuration of the server system 310 (shown in FIG. 3) of the system 300 (shown in FIG. 3), in accordance with one embodiment of the present disclosure. Server computer device 501 may include, but is not limited to, WSA computer device 115 (shown in FIG. 1), database server 315, and WSA server 310 (both shown in FIG. 3). Server computer device 501 also includes a processor 505 for executing instructions. Instructions may be stored in a memory area 510. Processor 505 may include one or more processing units (e.g., in a multi-core configuration).

Processor 505 is operatively coupled to a communication interface 515 such that server computer device 501 is capable of communicating with a remote device such as another server computer device 501, another WSA server 310, or client system 325 (shown in FIG. 3). For example, communication interface 515 may receive requests from client system 325 via the Internet, as illustrated in FIG. 3.

Processor 505 may also be operatively coupled to a storage device 534. Storage device 534 is any computer-operated hardware suitable for storing and/or retrieving data, such as, but not limited to, data associated with database 320 (shown in FIG. 3). In some embodiments, storage device 534 is integrated in server computer device 501. For example, server computer device 501 may include one or more hard disk drives as storage device 534. In other embodiments, storage device 534 is external to server computer device 501 and may be accessed by a plurality of server computer devices 501. For example, storage device 534 may include a storage area network (SAN), a network attached storage (NAS) system, and/or multiple storage units such as hard disks and/or solid state disks in a redundant array of inexpensive disks (RAID) configuration.

In some embodiments, processor 705 is operatively coupled to storage device 534 via a storage interface 520. Storage interface 520 is any component capable of providing processor 505 with access to storage device 534. Storage interface 520 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 505 with access to storage device 534.

Processor 505 executes computer-executable instructions for implementing aspects of the disclosure. In some embodiments, the processor 505 is transformed into a special purpose microprocessor by executing computer-executable instructions or by otherwise being programmed. For example, the processor 505 is programmed with instructions such as illustrated in FIG. 2.

FIG. 6 illustrates a block diagram of a prediction model 600 for post-DGRD wafer thickness in accordance with at least one embodiment of the disclosure. More specifically, model 600 illustrates a prediction model and system data flow design. Model 600 illustrates feature or sequence information extraction. Model 600 is a combination of MLP, LSTM, and convolutional layers to handle sequence type data.

In model 600, multi-modal inputs 605 are fed into a deep neural network 610 to provide multi-modal, post DGRD prediction outputs 615. The multi-modal inputs 605 may include, but are not limited to, multi-dimensional process sequence data 620, multi-dimensional wafer shape or thickness profiles 625, one-dimensional numerical data 630, and/or one-dimensional nominal data 635. This includes sequence frame data 620, such as the grinding process log and the results of the real-time recoding per second including detailed machine status data or setting data. The multi-dimensional wafer shape or thickness profiles 625 may be for previous runs or DGRD outputs. These may have been provided by the measurement devices 305 and/or the WSA computer device 310 (both shown in FIG. 3) for historical and/or previous runs. The numerical data 620 includes live data from the measurement devices 305, such as the thickness sensors 112 (both shown in FIG. 1). The nominal data 635 includes grinder information, recipe, and other needed data.

The process sequence data 620 is used for feature extractions by a combination of LSTM and/or transformer blocks 640. The wafer shape or thickness profiles 625 are used by a combination of convolution and/or transformer blocks 645. The numerical data 630 may be used with MLP blocks 650. And the nominal data 635 may be embedded into blocks 655. These are combined using semantic fusion into fully connected layers 660.

The deep neural network 610 is executed to provide the outputs 615. The outputs 615 include, but are not limited to, outputting variables 665, such as, but not limited to, thickness, TTV (total thickness variation), and/or shape metrics like bow and Warp. The output 615 also includes up sampling blocks 670 to provide multi-dimensional wafer shape or thickness profiles.

The systems and methods describes herein may include some and/or all of the functionality described herein. Furthermore, one having ordinary skill in the art would understand that some or all of the elements described herein may be rearranged and/or edited per the needs of the user.

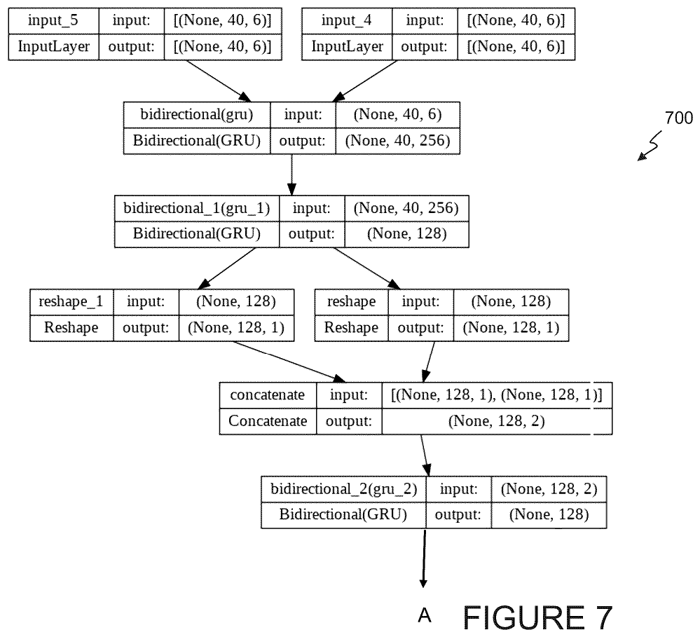

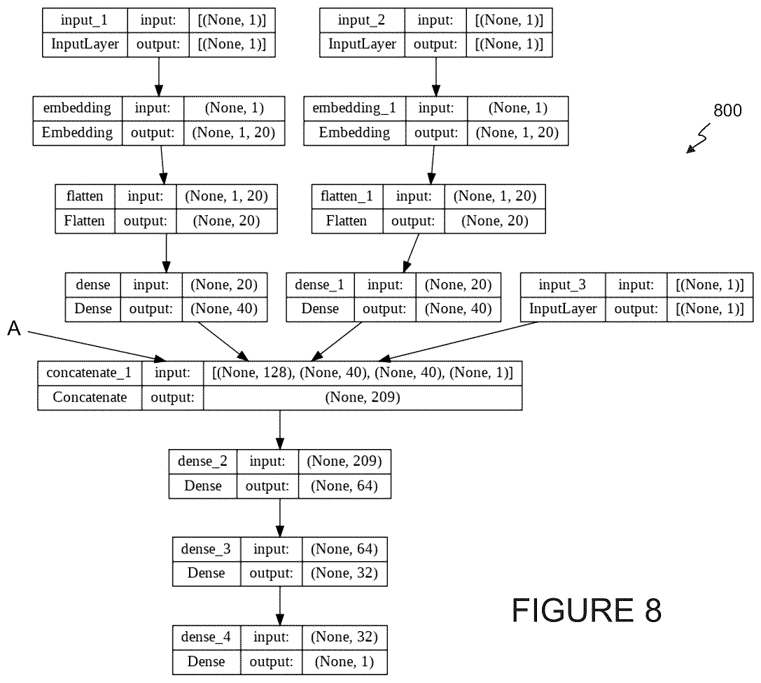

FIG. 7 illustrates a first part of a detailed deep learning architecture 700. Architecture 700 receives two sets of inputs for embedding, including historical wafer sequence input as shown on the top left and real-time wafer sequence input as shown in the top right. The next two layers include BILSTM (bidirectional long short-term memory) to extra features from the provided data. Then the BiLSTM is used to fuse different wafers. This is then provided to the rest of the system as shown in FIG. 8.

FIG. 8 illustrates a second part of a detailed deep learning architecture 800 to be used with the architecture 700 (shown in FIG. 7). FIG. 8 illustrates receiving nominal inputs 635 at the top and then using that data with embedding blocks 655 (both shown in FIG. 6). In architecture the nominal inputs 635 are combined with the output of architecture 700 shown on the left and numerical inputs 630 shown on the right. This may be combined using MLP blocks 650 and full connected layers 660 (both shown in FIG. 6) for mulit-input fusion. Then the output 615 can be down-sampled to provide simple metric values or up-sampled 670 to provide wafer profiles 675 (all shown in FIG. 6).

Architectures 700 and 800 combine to provide different feature extraction blocks. This complies with the model 600 (shown in FIG. 6). These architectures are also scalable layer plots and editable remarks.

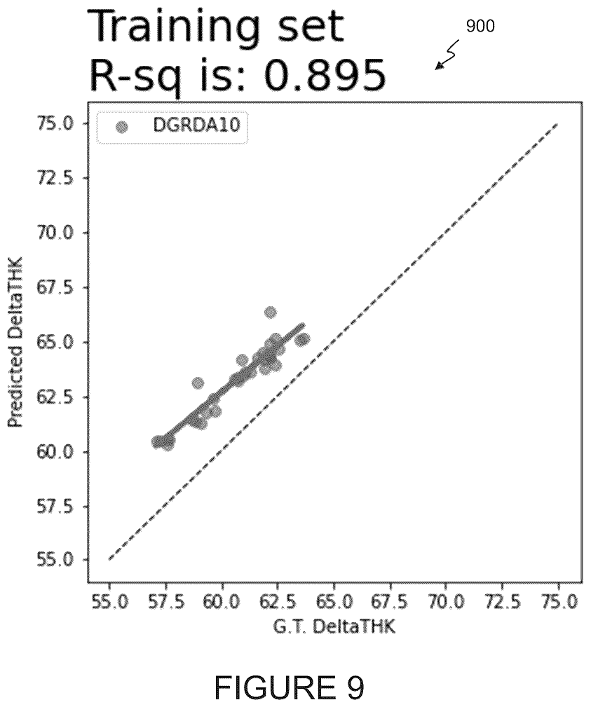

FIG. 9 illustrates a graph 900 of outlier information for an example grinder 105 (shown in FIG. 1). In graph 900, the grinder does not completely meet the prediction if sufficient input features/information are not provided. Graph 900 illustrates a significant deviation.

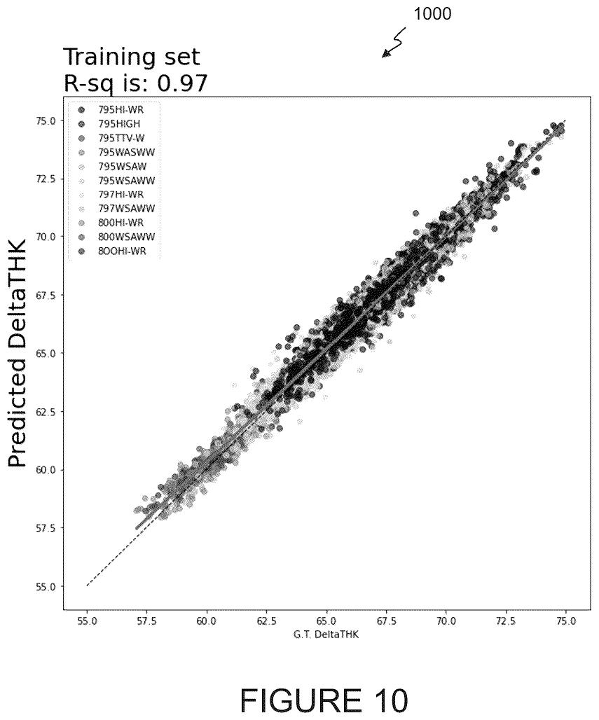

FIG. 10 illustrates a graph 1000 illustrating a correlation and R-square between ground truth and prediction of post-DGRD thickness when provided for an example. The processes of the present disclosure are further illustrated by the following Example. This Example should not be viewed in a limiting sense.

An initial model was evaluated with a dataset composed of 17,000 wafers. The ground truth value with predicted value of post-DGRD thickness is plotted, and the R-square is checked as shown FIG. 10. The prediction error range is about +−1.5 um.

At least one of the technical solutions provided by this system to address technical problems may include: (i) improved analysis of wafer thicknesses; (ii) decreased loss of material due to malfunction or improper alignment; (iii) increased speed in wafer analysis; (iv) increased accuracy in wafer analysis; (v) reduced unnecessary adjustments to the grinder; (vi) reduced false positives and false negatives; and (vii) updated analysis calibrated for each individual production grinders.

The computer-implemented methods discussed herein may include additional, less, or alternate actions, including those discussed elsewhere herein. The methods may be implemented via one or more local or remote processors, transceivers, servers, and/or sensors (such as processors, transceivers, servers, and/or sensors mounted on vehicles or mobile devices, or associated with smart infrastructure or remote servers), and/or via computer-executable instructions stored on non-transitory computer-readable media or medium.

Additionally, the computer systems discussed herein may include additional, less, or alternate functionality, including that discussed elsewhere herein. The computer systems discussed herein may include or be implemented via computer-executable instructions stored on non-transitory computer-readable media or medium.

A processor or a processing element may be trained using supervised or unsupervised machine learning, and the machine learning program may employ a neural network, which may be a convolutional neural network, a deep learning neural network, a reinforced or reinforcement learning module or program, or a combined learning module or program that learns in two or more fields or areas of interest. Machine learning may involve identifying and recognizing patterns in existing data in order to facilitate making predictions for subsequent data. Models may be created based upon example inputs in order to make valid and reliable predictions for novel inputs.

Additionally or alternatively, the machine learning programs may be trained by inputting sample data sets or certain data into the programs, such as images, object statistics and information, historical estimates, and/or actual repair costs. The machine learning programs may utilize deep learning algorithms that may be primarily focused on pattern recognition, and may be trained after processing multiple examples. The machine learning programs may include Bayesian Program Learning (BPL), voice recognition and synthesis, image or object recognition, optical character recognition, and/or natural language processing-either individually or in combination. The machine learning programs may also include natural language processing, semantic analysis, automatic reasoning, and/or machine learning.

Supervised and unsupervised machine learning techniques may be used. In supervised machine learning, a processing element may be provided with example inputs and their associated outputs, and may seek to discover a general rule that maps inputs to outputs, so that when subsequent novel inputs are provided the processing element may, based upon the discovered rule, accurately predict the correct output. In unsupervised machine learning, the processing element may be required to find its own structure in unlabeled example inputs. In one embodiment, machine learning techniques may be used to extract data about wafer surface nanotopography to predict future states.

Based upon these analyses, the processing element may learn how to identify characteristics and patterns that may then be applied to analyzing image data, model data, and/or other data. For example, the processing element may learn, to identify trends that precede a grinder coming out of alignment based upon comparisons of post grinding and post polishing measurements. The processing element may also learn how to identify trends that may not be readily apparent based upon collected scan data, such as trends that precede a grinder coming out of alignment.

The methods and system described herein may be implemented using computer programming or engineering techniques including computer software, firmware, hardware, or any combination or subset. As disclosed above, at least one technical problem with prior systems is that there is a need for systems for a cost-effective and reliable manner for analyzing data to predict wafer thickness. The system and methods described herein address that technical problem. Additionally, at least one of the technical solutions provided by this system to overcome technical problems may include: (i) improved analysis of wafer surfaces; (ii) decreased loss of material due to malfunction or improper alignment; (iii) increased speed in wafer analysis; (iv) increased accuracy in wafer analysis; and (v) updated analysis calibrated for each individual production line.

The methods and systems described may be implemented using computer programming or engineering techniques including computer software, firmware, hardware, or any combination or subset thereof, wherein the technical effects may be achieved by performing at least one of the following steps: (a) store, in the at least one memory device, a model for predicting post-grinding thickness of a wafer; (b) receive scan data of a first inspection of a wafer; (c) execute the model using the scan data as inputs to determine a final thickness of the wafer; (d) compare the final thickness to one or more thresholds; (e) determine if the final thickness exceeds at least one of the one or more thresholds; (f) if the determination is that the final thickness exceeds at least one of the one or more thresholds, cause a grinding station to be adjusted; (g) wherein the scan data is from before grinding the wafer; (h) wherein the grinding station is adjusted before the wafer is ground; (i) wherein the scan data is from during grinding the wafer; (j) wherein the grinding station is adjusted while the wafer is being ground; (k) wherein the scan data is from subsequent to grinding the wafer; (l) wherein the grinding station is adjusted prior to a subsequent wafer being ground; (m) wherein the scan data includes data from one or more thickness sensors configured to measure a thickness of the wafer; (n) wherein the first inspection is positioned subsequent to the grinding station; (o) wherein the grinding station includes a front grinder and a back grinder for grinding both sides of the wafer; (p) generate the model for predicting a thickness of a post-grinding wafer based upon at least one of real-time grinder parameters, previous historical wafer logs, and process recipes; (q) wherein the wafer is a semiconductor wafer; (r) generate one or more adjustments to the grinding station based on the comparison of the final thickness to one or more thresholds and the model; (s) transmit the one or more adjustments to at least one of a user and the grinding station; and/or (t) if the determination is that the final thickness exceeds at least one of the one or more thresholds, (1) analyze a plurality of prior inspections to determine a trend; (2) predict if a subsequent inspection of a subsequent wafer may exceed at least one of the one or more thresholds based on the trend; and/or (3) adjust the grinding station based on the trend.

### ADDITIONAL CONSIDERATIONS

As will be appreciated based upon the foregoing specification, the above-described embodiments of the disclosure may be implemented using computer programming or engineering techniques including computer software, firmware, hardware or any combination or subset thereof. Any such resulting program, having computer-readable code means, may be embodied or provided within one or more computer-readable media, thereby making a computer program product, i.e., an article of manufacture, according to the discussed embodiments of the disclosure. The computer-readable media may be, for example, but is not limited to, a fixed (hard) drive, diskette, optical disk, magnetic tape, semiconductor memory such as read-only memory (ROM), and/or any transmitting/receiving medium such as the Internet or other communication network or link. The article of manufacture containing the computer code may be made and/or used by executing the code directly from one medium, by copying the code from one medium to another medium, or by transmitting the code over a network.

These computer programs (also known as programs, software, software applications, “apps,” or code) include machine instructions for a programmable processor and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, the terms “processor” and “computer” and related terms, e.g., “processing device”, “computing device”, and “controller” are not limited to just those integrated circuits referred to in the art as a computer, but broadly refers to a microcontroller, a microcomputer, a programmable logic controller (PLC), a reduced instruction set circuit (RISC), an application specific integrated circuit (ASIC), logic circuits, and any other circuit or processor capable of executing the functions described herein. The above examples are example only and are thus not intended to limit in any way the definition and/or meaning of the term “processor.”

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

As used herein, the term “database” can refer to either a body of data, a relational database management system (RDBMS), or to both. As used herein, a database can include any collection of data including hierarchical databases, relational databases, flat file databases, object-relational databases, object-oriented databases, and any other structured collection of records or data that is stored in a computer system. The above examples are example only, and thus are not intended to limit in any way the definition and/or meaning of the term database. Examples of RDBMS' include, but are not limited to including, Oracle® Database, MySQL, IBM® DB2, Microsoft® SQL Server, Sybase®, and PostgreSQL. However, any database can be used that enables the systems and methods described herein. (Oracle is a registered trademark of Oracle Corporation, Redwood Shores, California; IBM is a registered trademark of International Business Machines Corporation, Armonk, New York; Microsoft is a registered trademark of Microsoft Corporation, Redmond, Washington; and Sybase is a registered trademark of Sybase, Dublin, California.)

In another example, a computer program is provided, and the program is embodied on a computer-readable medium. In an example, the system is executed on a single computer system, without requiring a connection to a server computer. In a further example, the system is being run in a Windows® environment (Windows is a registered trademark of Microsoft Corporation, Redmond, Washington). In yet another example, the system is run on a mainframe environment and a UNIX® server environment (UNIX is a registered trademark of X/Open Company Limited located in Reading, Berkshire, United Kingdom). In a further example, the system is run on an iOS® environment (iOS is a registered trademark of Cisco Systems, Inc. located in San Jose, CA). In yet a further example, the system is run on a Mac OS® environment (Mac OS is a registered trademark of Apple Inc. located in Cupertino, CA). In still yet a further example, the system is run on Android® OS (Android is a registered trademark of Google, Inc. of Mountain View, CA). In another example, the system is run on Linux® OS (Linux is a registered trademark of Linus Torvalds of Boston, MA). The application is flexible and designed to run in various different environments without compromising any major functionality.

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

Furthermore, as used herein, the term “real-time” refers to at least one of the time of occurrence of the associated events, the time of measurement and collection of predetermined data, the time to process the data, and the time of a system response to the events and the environment. In the examples described herein, these activities and events occur substantially instantaneously.

In some embodiments, the system includes multiple components distributed among a plurality of computer devices. One or more components may be in the form of computer-executable instructions embodied in a computer-readable medium. The systems and processes are not limited to the specific embodiments described herein. In addition, components of each system and each process can be practiced independent and separate from other components and processes described herein. Each component and process can also be used in combination with other assembly packages and processes. The present embodiments may enhance the functionality and functioning of computers and/or computer systems.

The computer-implemented methods discussed herein can include additional, less, or alternate actions, including those discussed elsewhere herein. The methods can be implemented via one or more local or remote processors, transceivers, servers, and/or sensors (such as processors, transceivers, servers, and/or sensors mounted on vehicles or mobile devices, or associated with smart infrastructure or remote servers), and/or via computer-executable instructions stored on non-transitory computer-readable media or medium. Additionally, the computer systems discussed herein can include additional, less, or alternate functionality, including that discussed elsewhere herein. The computer systems discussed herein can include or be implemented via computer-executable instructions stored on non-transitory computer-readable media or medium.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein can be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

The patent claims at the end of this document are not intended to be construed under 35 U.S.C. § 112(f) unless traditional means-plus-function language is expressly recited, such as “means for” or “step for” language being expressly recited in the claim(s).

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A computer device comprising at least one processor in communication with at least one memory device, wherein the at least one processor is programmed to:
store, in the at least one memory device, a model for predicting post-grinding thickness of a wafer;
receive scan data of a first inspection of a wafer;
execute the model using the scan data as inputs to determine a final thickness of the wafer;
compare the final thickness to one or more thresholds;
determine if the final thickness exceeds at least one of the one or more thresholds; and
cause a grinding station to be adjusted when it is determined that the final thickness exceeds at least one of the one or more thresholds.

2. The computer device of claim 1, wherein the scan data is from before grinding the wafer.

3. The computer device of claim 2, wherein the grinding station is adjusted before the wafer is ground.

4. The computer device of claim 1, wherein the scan data is from during grinding the wafer.

5. The computer device of claim 4, wherein the grinding station is adjusted while the wafer is being ground.

6. The computer device of claim 1, wherein the scan data is from subsequent to grinding the wafer.

7. The computer device of claim 6, wherein the grinding station is adjusted prior to a subsequent wafer being ground.

8. The computer device of claim 1, wherein the scan data includes data from one or more thickness sensors configured to measure a thickness of the wafer.

9. The computer device of claim 1, wherein the scan data includes data collected subsequent to the grinding station.

10. The computer device of claim 1, wherein the grinding station includes a front grinder and a back grinder for grinding both sides of the wafer.

11. The computer device of claim 1, wherein the at least one processor is further programmed to generate the model for predicting a thickness of a post-grinding wafer based upon at least one of real-time grinder parameters, previous historical wafer logs, and process recipes.

12. The computer device of claim 1, wherein the wafer is a semiconductor wafer.

13. The computer device of claim 1, wherein the at least one processor is further programmed to:
generate one or more adjustments to the grinding station based on the comparison of the final thickness to one or more thresholds and the model; and
transmit the one or more adjustments to at least one of a user and the grinding station.

14. The computer device of claim 1, wherein, upon determining that the final thickness exceeds at least one of the one or more thresholds, the at least one processor is further programmed to:
analyze a plurality of prior inspections to determine a trend;
predict if a subsequent inspection of a subsequent wafer may exceed at least one of the one or more thresholds based on the trend; and
adjust the grinding station based on the trend.

15. A method for analyzing a wafer, the method implemented by a computing device including at least one processor in communication with at least one memory device, the method comprising:
storing, in the at least one memory device, a model for predicting post-grinding thickness of a wafer;
receiving scan data of a first inspection of a wafer;
executing the model using the scan data as inputs to determine a final thickness of the wafer;
comparing the final thickness to one or more thresholds;
determining if the final thickness exceeds at least one of the one or more thresholds; and
causing a grinding station to be adjusted when it is determined that the final thickness exceeds at least one of the one or more thresholds.

16. The method of claim 15, wherein the scan data includes data from one or more thickness sensors configured to measure a thickness of the wafer, wherein the scan data includes data collected subsequent to the grinding station, and wherein the grinding station includes a front grinder and a back grinder for grinding both sides of the wafer.

17. The method of claim 15 further comprising generating the model for predicting a thickness of a post-grinding wafer based upon at least one of real-time grinder parameters, previous historical wafer logs, and process recipes.

18. The method of claim 15 further comprising:
generating one or more adjustments to the grinding station based on the comparison of the final thickness to one or more thresholds and the model; and
transmitting the one or more adjustments to at least one of a user and the grinding station.

19. The method of claim 15, upon determining that the final thickness exceeds at least one of the one or more thresholds, the method further comprises:
analyzing a plurality of prior inspections to determine a trend;
predicting if a subsequent inspection of a subsequent wafer may exceed at least one of the one or more thresholds based on the trend; and
adjusting the grinding station based on the trend.

20. The method of claim 15, wherein the wafer is a semiconductor wafer.
